(19) United States
(12) Patent Application Publication
(10) Pub. No.: US 2025/0185155 A1
(43) Pub. Date: Jun. 5, 2025

(54) Printed Circuit Board and Display Device

(71) Applicant: LG Display Co., Ltd., Seoul (KR)

(72) Inventors: JuHyun Ji, Paju-si (KR); Dongju Kim, Paju-si (KR)

(21) Appl. No.: 18/962,155

(22) Filed: Nov. 27, 2024

(30) Foreign Application Priority Data
Dec. 4, 2023 (KR) 10-2023-0173639

(51) Int. Cl. H05K 1/02

(52) U.S. Cl. CPC H05K 1/025; H05K 2201/10128

(57) ABSTRACT

Embodiments of the disclosure relate to a printed circuit board and a display device and, more specifically, may include a display panel and a printed circuit board directly or indirectly connected to the display panel and including a plurality of layers. The printed circuit board may include a first substrate layer, a second substrate layer disposed on the first substrate layer and having a slit formed in at least a portion thereof, a signal line disposed on the second substrate layer, disposed in a direction forming a predetermined angle from a longitudinal direction of the slit, and passing over the slit so that at least a portion thereof overlaps the slit on the same vertical line, and an impedance matching element connected to the signal line.

### CROSS-REFERENCE TO RELATED APPLICATION

This application claims priority from Republic of Korea Patent Application No. 10-2023-0173639 filed on Dec. 4, 2023, which is hereby incorporated by reference in its entirety.

### BACKGROUND

### Field

Embodiments of the disclosure relate to a printed circuit board and a display device.

### Description of Related Art

A printed circuit board (PCB) is a printed wiring board in which electrical lines between electrical components or circuits are formed on an insulation layer based on a circuit design and may be simply referred to as a PCB.

These printed circuit boards are also used in display devices for electrical connections between electronic components or circuits.

A printed circuit board may have at least one signal line disposed thereon, and the impedance of the signal line may increase depending on the structure of the printed circuit board. Depending on the structure of the printed circuit board, an abrupt change in impedance may occur in the signal line, in which case the signal shape may be distorted or the quality of signal transfer (communication) through the signal line may deteriorate.

### SUMMARY

Embodiments of the disclosure may provide a printed circuit board and a display device including the same, which may prevent or at least reduce an abrupt change in impedance while having an effective multi-layer structure through a slit structure including a plurality of slits disposed to be spaced apart from each other for insulation between signal lines.

Embodiments of the disclosure may provide a printed circuit board and a display device which may mitigate the impedance peak issue, that occurs in a signal line, caused by a slit.

Embodiments of the disclosure may provide a printed circuit board and a display device which may mitigate an impedance peak by temporarily decreasing an abrupt change in impedance caused by a slit by connecting an impedance matching element to a signal line.

Embodiments of the disclosure may provide a printed circuit board and a display device which may maintain communication quality while preventing distortion of a signal shape by mitigating an abrupt change in impedance.

A display device according to embodiments of the disclosure may comprise a display panel, and a printed circuit board directly or indirectly connected to the display panel and including a plurality of layers. The printed circuit board may include a first substrate layer, a second substrate layer disposed on the first substrate layer and having a slit formed in at least a portion thereof, a signal line disposed on the second substrate layer, disposed in a direction forming a predetermined angle from a longitudinal direction of the slit, and passing over the slit so that a portion thereof overlaps the slit on a vertical line of the slit, and an impedance matching element electrically connected to the signal line.

A printed circuit board according to embodiments of the disclosure may comprise a first substrate layer, a second substrate layer disposed on the first substrate layer and including a slit, a signal line disposed on the second substrate layer, disposed in a direction forming a predetermined angle from a longitudinal direction of the slit, and passing over the slit so that at least a portion thereof overlaps the slit on the same vertical line, and an impedance matching element connected to the signal line.

A printed circuit board according to embodiment of the disclosure may comprise a substrate layer including a slit, a signal line on the substrate layer, the signal line wired in a direction forming a predetermined angle from a longitudinal direction of the slit and passing over the slit such that a portion thereof may overlap the slit on a vertical line of the slit, and a first element and a second element for decreasing an abrupt change, caused by the slit, in impedance of the signal line. The first element may contact or be adjacent to a first side wall of the slit, and be connected to the signal line. The second element may contact or be adjacent to a second side wall of the slit opposite to the first side wall, and be connected to the signal line. Each of the first and second elements may be formed in a protrusion shape protruding outward from the signal line.

Embodiments of the disclosure may provide a printed circuit board and a display device including the same, which may prevent an abrupt change in impedance while having an effective multi-layer structure through a slit structure including a plurality of slits disposed to be spaced apart from each other for insulation between signal lines.

According to embodiments of the disclosure, it is possible to mitigate an impedance peak issue that occurs in a signal line caused by a slit.

According to embodiments of the disclosure, it is possible to mitigate an impedance peak by temporarily decreasing an abrupt change in impedance at a slit boundary by connecting an impedance matching element to a signal line.

According to embodiments of the disclosure, it is possible to maintain communication quality while preventing or at least reducing distortion of a signal shape by mitigating an abrupt change in impedance.

### BRIEF DESCRIPTION OF DRAWINGS

The above and other objects, features, and advantages of the disclosure will be more clearly understood from the following detailed description, taken in conjunction with the accompanying drawings, in which:

FIG. 1 is a view illustrating a system configuration of a display device according to embodiments of the disclosure;

FIG. 2 is a view schematically illustrating a configuration of a display device according to an embodiment of the disclosure;

FIG. 3 is a view schematically illustrating a configuration of a display device according to an embodiment of the disclosure;

FIG. 4 is a plan view illustrating a portion of a printed circuit board according to an embodiment of the disclosure;

FIG. 5 is an example cross-sectional view illustrating a portion of a printed circuit board according to an embodiment of the disclosure;

FIG. 6 is another example cross-sectional view illustrating a portion of a printed circuit board according to an embodiment of the disclosure;

FIG. 7 is a cross-sectional view illustrating a printed circuit board having an impedance matching element according to an embodiment of the disclosure;

FIG. 8 is a graph illustrating changes in impedance of a signal line when an impedance matching element is connected to a signal line and when an impedance matching element is not connected to a signal line according to an embodiment of the disclosure;

FIG. 9 is an enlarged plan view illustrating a portion of an impedance matching element according to an embodiment of the disclosure;

FIG. 10 is a graph illustrating an impedance peak mitigating effect by an impedance matching element according to an embodiment of the disclosure;

FIG. 11 illustrates an example of a placement position of an impedance matching element according to an embodiment of the disclosure;

FIG. 12 is a graph illustrating a difference in impedance of a signal line according to a placement position of an impedance matching element according to an embodiment of the disclosure;

FIG. 13 is an example view illustrating various sizes of an impedance matching element according to an embodiment of the disclosure;

FIG. 14 is a graph illustrating a difference in impedance of a signal line according to various sizes of an impedance matching element according to an embodiment of the disclosure;

FIG. 15 illustrates a plan view and cross-sectional views of a printed circuit board having a platooning management entity according to an embodiment of the disclosure;

FIG. 16 is a plan view illustrating an example of an impedance matching element structure according to an embodiment of the disclosure;

FIG. 17 is a perspective view illustrating a coupling structure between an impedance matching element and a printed circuit board according to an embodiment of the disclosure;

FIG. 18 is an eye diagram illustrating differential signal states before an impedance peak is mitigated and after an impedance peak is mitigated by an impedance matching element; and

FIG. 19 is a reference view illustrating an eye diagram.

### DETAILED DESCRIPTION

In the following description of examples or embodiments of the disclosure, reference will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the disclosure, detailed descriptions of well-known functions and components incorporated herein will be omitted when it is determined that the description may make the subject matter in some embodiments of the disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after,” “subsequent to,” “next,” “before,” and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the disclosure are described in detail with reference to the accompanying drawings.

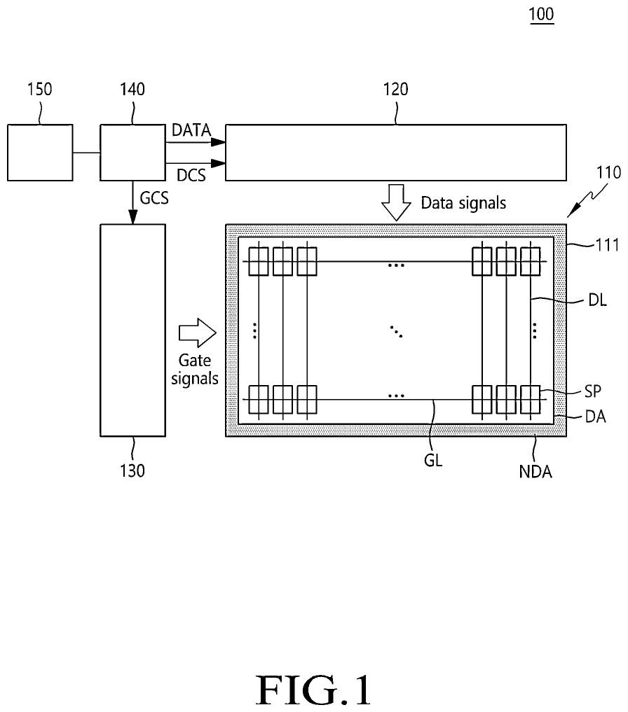

FIG. 1 is a view illustrating a system configuration of a display device according to embodiments of the disclosure;

Referring to FIG. 1, a display device 100 according to embodiments of the disclosure may include a display panel 110 and display driving circuits, as components for displaying images. The display driving circuits are circuits for driving the display panel 110 and may include a data driving circuit 120, a gate driving circuit 130, and a display controller 140.

The display panel 110 may include a substrate 111 and a plurality of subpixels SP disposed on the substrate 111.

The substrate 111 of the display panel 110 may include a display area DA capable of displaying an image and a non-display area NDA positioned outside the display area DA.

In the display panel 110 according to embodiments of the disclosure, the non-display area NDA may be very small.

For example, the non-display area NDA may include a first non-display area positioned outside the display area DA in a first direction, a second non-display area positioned outside the display area DA in a second direction crossing the first direction, a third non-display area positioned outside the display area DA in a direction opposite to the first direction, and a fourth non-display area positioned outside the display area DA in a direction opposite to the second direction. One or two of the first to fourth non-display areas may include a pad area where the data driving circuit 120 is connected or bonded. Two or three of the first to fourth non-display areas where the pad area is not included may be very small.

As another example, the boundary area between the display area DA and the non-display area NDA may be bent so that the non-display area NDA may be positioned under the display area. In this case, no or little change may be made to the non-display area NDA shown to the user when the user views the display area 100 from the front.

Various types of signal lines for driving a plurality of subpixels SP may be disposed on the substrate 111 of the display panel 110.

The display device 100 according to embodiments of the disclosure may be a liquid crystal display device or a self-emission display device in which the display panel 110 emits light by itself. When the display device 100 according to the embodiments of the disclosure is a self-emission display device, each of the plurality of subpixels SP may include a light emitting element.

For example, the display device 100 according to embodiments of the disclosure may be an organic light emitting diode display in which the light emitting element is implemented as an organic light emitting diode (OLED). As another example, the display device 100 according to embodiments of the disclosure may be an inorganic light emitting display device in which the light emitting element is implemented as an inorganic material-based light emitting diode. As another example, the display device 100 according to embodiments of the disclosure may be a quantum dot display device in which the light emitting element is implemented as a quantum dot which is self-emission semiconductor crystal.

The structure of each of the plurality of subpixels SP may vary according to the type of the display device 100. For example, when the display device 100 is a self-emission display device in which the subpixels SP emit light by themselves, each subpixel SP may include a light emitting element that emits light by itself, one or more transistors, and one or more capacitors.

For example, various types of signal lines may include a plurality of data lines DL transferring data signals (also referred to as data voltages or image signals) and a plurality of gate lines GL transferring gate signals (also referred to as scan signals).

The plurality of data lines DL and the plurality of gate lines GL may cross each other. Each of the plurality of data lines DL may be disposed to extend in the first direction. Each of the plurality of gate lines GL may be disposed to extend in the second direction. Here, the first direction may be a column direction and the second direction may be a row direction. The first direction may be the row direction, and the second direction may be the column direction. For convenience of description, described below is an example in which each of the plurality of data lines DL is disposed in the column direction, and each of the plurality of gate lines GL is disposed in the row direction.

The data driving circuit 120 is a circuit for driving the plurality of data lines DL, and may out data signals to the plurality of data lines DL.

The data driving circuit 120 may receive digital image data DATA from the display controller 140 and may convert the received image data DATA into analog data signals and output them to the plurality of data lines DL.

For example, the data driving circuit 120 may be connected with the display panel 110 by a tape automated bonding (TAB) method or connected to a bonding pad of the display panel 110 by a chip on glass (COG) or chip on panel (COP) method or may be implemented by a chip on film (COF) method and connected with the display panel 110.

The data driving circuit 120 may be connected to one side (e.g., an upper or lower side) of the display panel 110. In contrast, depending on the driving scheme or the panel design scheme, data driving circuits 120 may be connected with both the sides (e.g., both the upper and lower sides) of the display panel 110, or two or more of the four sides of the display panel 110.

The data driving circuit 120 may be connected outside the display area DA of the display panel 110, but alternatively, the data driving circuit 120 may be disposed in the display area DA of the display panel 110.

The gate driving circuit 130 is a circuit for driving the plurality of gate lines GL, and may output gate signals to the plurality of gate lines GL. The gate driving circuit 130 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

In the display device 100 according to embodiments of the disclosure, the gate driving circuit 130 may be embedded, in a gate in panel (GIP) type, in the display panel 110. When the gate driving circuit 130 is of the gate in panel type, the gate driving circuit 130 may be formed on the substrate 111 of the display panel 110 during the manufacturing process of the display panel 110. In the display device 100 according to embodiments of the disclosure, the gate driving circuit 130 may be disposed in the display area DA of the display panel 110. For example, the gate driving circuit 130 may be disposed in a first partial area in the display area DA (e.g., a left area or a right area in the display area DA). As another example, the gate driving circuit 130 may be disposed in a first partial area in the display area DA (e.g., a left area or right area in the display area DA) and a second partial area (e.g., a right area or left area in the display area DA).

In the disclosure, the gate driving circuit 130 embedded in the display panel 110 in a gate-in-panel type may also be referred to as a “gate-in-panel circuit.”

The display controller 140 is a device for controlling the data driving circuit 120 and the gate driving circuit 130 and may control driving timings for the plurality of data lines DL and driving timings for the plurality of gate lines GL.

The display controller 140 may supply the data driving control signal DCS to the data driving circuit 120 to control the data driving circuit 120.

The display controller 140 may supply the gate driving control signal GCS to the gate driving circuit 130 to control the gate driving circuit 130.

The display controller 140 may receive input image data from the host system 150 and supply image data DATA to the data driving circuit 120 based on the input image data.

The display controller 140 may be implemented as a separate component from the data driving circuit 120, or the display controller 140 and the data driving circuit 120 may be integrated into an integrated circuit (IC).

The display controller 140 may be a timing controller used in typical display technology, a control device that may perform other control functions as well as the functions of the timing controller, or a control device other than the timing controller, or may be a circuit in the control device. The display controller 140 may be implemented as various circuits or electronic components, such as an integrated circuit (IC), a field programmable gate array (FPGA), an application specific integrated circuit (ASIC), or a processor.

The display controller 140 may be mounted on a printed circuit board or a flexible printed circuit and may be electrically connected with the data driving circuit 120 and the gate driving circuit 130 through the printed circuit board or the flexible printed circuit.

The display controller 140 may transmit/receive signals to/from the data driving circuit 120 according to one or more predetermined interfaces. The interface may include, e.g., a low voltage differential signaling (LVDS) interface, an embedded clock point-point interface (EPI) interface, and a serial peripheral interface (SPI).

To provide a touch sensing function as well as an image display function, the display device 100 according to embodiments of the disclosure may include a touch sensor and a touch sensing circuit that senses the touch sensor to detect whether a touch occurs by a touch object, such as a finger or pen, or the position of the touch.

The touch sensing circuit may include a touch driving circuit that drives and senses the touch sensor and generates and outputs touch sensing data and a touch controller that may detect an occurrence of a touch or the position of the touch using touch sensing data.

The touch sensor may include a plurality of touch electrodes. The touch sensor may further include a plurality of touch lines for electrically connecting the plurality of touch electrodes and the touch driving circuit.

The touch sensor may be present in a touch panel form outside the display panel 110 or may be present inside the display panel 110. When the touch panel, in the form of a touch panel, exists outside the display panel 110, the touch panel is referred to as an external type. When the touch sensor is of the external type, the touch panel and the display panel 110 may be separately manufactured or may be combined during an assembly process. The external-type touch panel may include a touch panel substrate and a plurality of touch electrodes on the touch panel substrate.

When the touch sensor is present inside the display panel 110, the touch sensor may be formed on the substrate, together with signal lines and electrodes related to display driving, during the manufacturing process of the display panel 110.

The touch driving circuit may supply a touch driving signal to at least one of the plurality of touch electrodes and may sense at least one of the plurality of touch electrodes to generate touch sensing data.

The touch sensing circuit may perform touch sensing in a self-capacitance sensing scheme or a mutual-capacitance sensing scheme.

When the touch sensing circuit performs touch sensing in the self-capacitance sensing scheme, the touch sensing circuit may perform touch sensing based on capacitance between each touch electrode and the touch object (e.g., finger or pen). According to the self-capacitance sensing scheme, each of the plurality of touch electrodes may serve both as a driving touch electrode and as a sensing touch electrode. The touch driving circuit may drive all or some of the plurality of touch electrodes and sense all or some of the plurality of touch electrodes.

When the touch sensing circuit performs touch sensing in the mutual-capacitance sensing scheme, the touch sensing circuit may perform touch sensing based on capacitance between the touch electrodes. According to the mutual-capacitance sensing scheme, the plurality of touch electrodes are divided into driving touch electrodes and sensing touch electrodes. The touch driving circuit may drive the driving touch electrodes and sense the sensing touch electrodes.

The touch driving circuit and the touch controller included in the touch sensing circuit may be implemented as separate devices or as a single device. The touch driving circuit and the data driving circuit may be implemented as separate devices or as a single device.

The display device 100 may further include a power supply circuit for supplying various types of power to the display driver integrated circuit and/or the touch sensing circuit. The display device 100 according to embodiments of the disclosure may be a mobile terminal, such as a smart phone or a tablet, or a monitor or television (TV) in various sizes but, without limited thereto, may be a display in various types and various sizes capable of displaying information or images.

The display device 100 according to embodiments of the disclosure may further include an electronic device such as a camera (image sensor), a detection sensor, or the like. For example, the detection sensor may be a sensor that detects an object or a human body by receiving light such as infrared rays, ultrasonic waves, or ultraviolet rays.

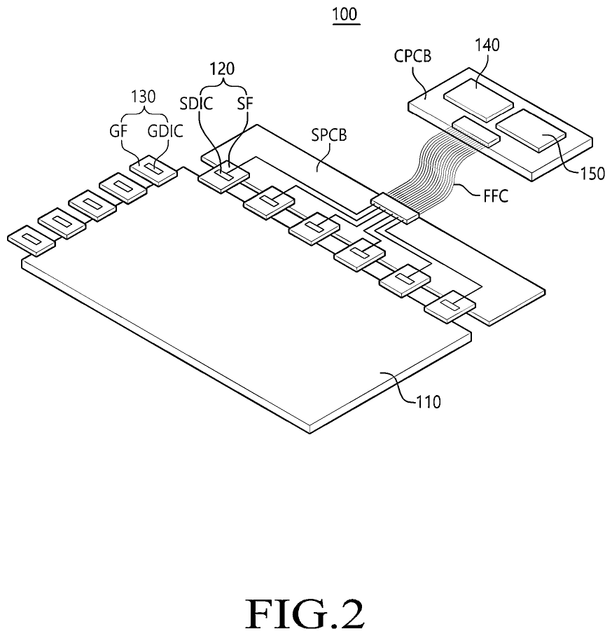

FIG. 2 is a view schematically illustrating a configuration of a display device according to embodiments of the disclosure.

Referring to FIG. 2, in the display device 100 according to embodiments of the disclosure, the source driving integrated circuit SDIC included in the data driving circuit 120 and the gate driving integrated circuit GDIC included in the gate driving circuit 130 are implemented in the chip-on-film (COF) type among various types (e.g., TAB, COG, or COF).

One or more gate driving integrated circuits GDIC included in the gate driving circuit 130 each may be mounted on a gate film GF, and one side of the gate film GF may be electrically connected with the display panel 110. Lines for electrically connecting the gate driving integrated circuit GDIC and the display panel 110 may be disposed on the gate film GF.

The gate driving circuit 130 may be located only on one side of the display panel 110 or on each of two opposite sides according to driving methods. The gate driving circuit 130 may be implemented in a gate-in-panel (GIP) form which is embedded in the bezel area of the display panel 110.

Likewise, one or more source driving integrated circuits SDIC included in the data driving circuit 120 each may be mounted on the source film SF, and one side of the source film SF may be electrically connected with the display panel 110. Lines for electrically connecting the source driver integrated circuit SDIC and the display panel 110 may be disposed on the source film SF.

The display device 100 may include a plurality of source driving integrated circuits SDIC and a printed circuit board for circuit connection between other devices. The printed circuit board may include, e.g., at least one source printed circuit board SPCB and a control printed circuit board CPCB for mounting control components and various electric devices.

In an embodiment, the other side of the source film SF where the source driving integrated circuit SDIC is mounted may be connected to at least one source printed circuit board SPCB. In other words, one side of the source film SF where the source driving integrated circuit SDIC is mounted may be electrically connected with the display panel 110, and the other side thereof may be electrically connected with the source printed circuit board SPCB.

The controller 140 and the power management circuit (power management IC) 150 may be mounted on the control printed circuit board CPCB. The controller 140 may control the operation of the data driving circuit 120 and the gate driving circuit 130. The power management circuit 150 may supply driving voltage or current to the display panel 110, the data driving circuit 120, and the gate driving circuit 130 and control the supplied voltage or current.

At least one source printed circuit board SPCB and control printed circuit board CPCB may be circuit-connected through at least one connection member. The connection member may include, e.g., a flexible printed circuit FPC or a flexible flat cable FFC. In this case, the connection member connecting the at least one source printed circuit board SPCB and control printed circuit board CPCB may be varied depending on the size and type of the display device 100. The at least one source printed circuit board SPCB and control printed circuit board CPCB may be integrated into a single printed circuit board.

In the so-configured display device 100, the power management circuit 150 transfers a driving voltage necessary for display driving or characteristic value sensing to the source printed circuit board SPCB through the flexible printed circuit FPC or flexible flat cable FFC. The driving voltage transferred to the source printed circuit board SPCB is supplied to emit light or sense a specific subpixel SP in the display panel 110 through the source driving integrated circuit SDIC.

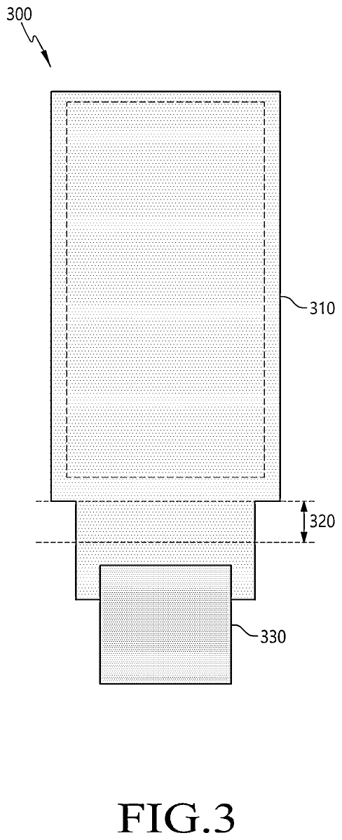

FIG. 3 is a view schematically illustrating a configuration of a display device according to an embodiment of the disclosure.

FIG. 3 is a view illustrating a display device according to embodiments of the disclosure.

FIG. 3 discloses a display device included in a mobile device.

A display panel 300 of a display device may include a substrate 310, a bending area 320, and an FPCB 330. The FPCB 330 is a flexible circuit board and may be disposed inside the mobile device. The FPCB 330 may electrically connect a plurality of components disposed inside the mobile device. To that end, a signal line may be disposed on the FPCB 330.

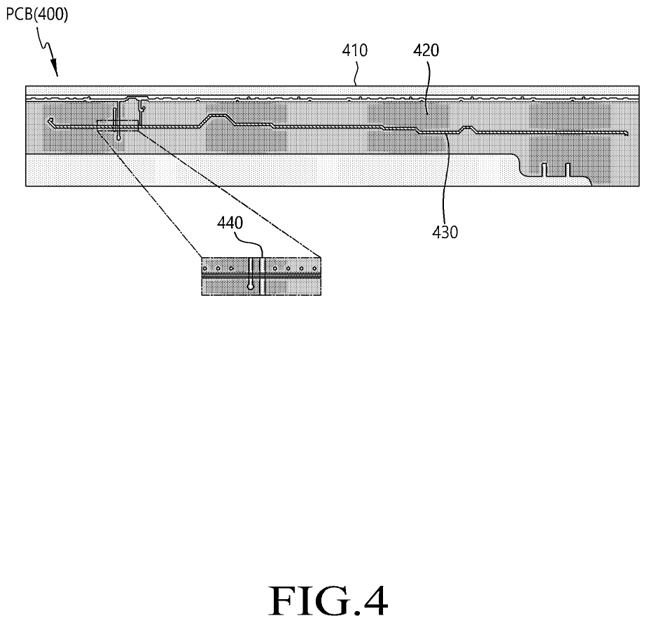

FIG. 4 is a plan view illustrating a portion of a printed circuit board according to an embodiment of the disclosure.

Referring to FIG. 4, a printed circuit board 400 includes a first substrate layer 410 and a second substrate layer 420. For convenience of description, only the first substrate layer 410 and the second substrate layer 420 of the multilayer structure of the printed circuit board are illustrated and represented, but the substrate layers constituting the multilayer structure of the printed circuit board 400 are not limited thereto.

The second substrate layer 420 may be disposed on the first substrate layer 410.

A dielectric layer disposed between the first substrate layer 410 and the second substrate layer 420 may be further included.

At least a portion of the second substrate layer 420 may be stacked on the first substrate layer 410, and may include a slit 440 and a signal line 430.

The signal line 430 may be disposed on the second substrate layer 420 while passing through or around the at least one slit 440.

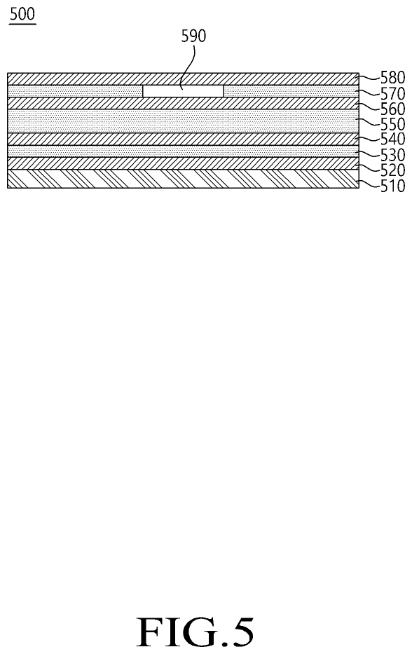

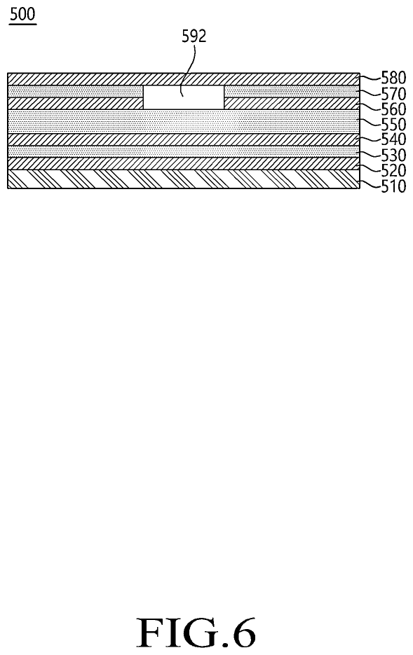

FIG. 5 is an example cross-sectional view illustrating a portion of a printed circuit board according to an embodiment of the disclosure. FIG. 6 is another example cross-sectional view illustrating a portion of a printed circuit board according to an embodiment of the disclosure. For reference, the printed circuit board 500 illustrated in FIGS. 5 and 6 is the same as the printed circuit board 400 illustrated in FIG. 4.

Referring to FIG. 5, the printed circuit board 500 may include a plurality of layers 510 to 580. Specifically, the printed circuit board 500 may include a plurality of metal layers 520, 540, 560, and 580 and a plurality of insulation layers 530, 550, and 570 in different layers on the layer 510 as a base substrate.

The insulation layers 530, 550, and 570 each may be disposed between the metal layers corresponding to the number of the plurality of metal layers 520, 540, 560, and 580.

For example, a first insulation layers 530 may be disposed between a first metal layer 520 and a second metal layer 540, a second insulation layers 550 may be disposed between the second metal layer 540 and a third metal layer 560, and a third insulation layers 570 may be disposed between the third metal layer 560 and a fourth metal layer 580.

Referring to FIGS. 4 and 5, the first slits 590 and 440 may be formed by etching at least a portion of the insulation layer 570 into a shape required for each circuit. In other words, the first slits 590 and 440 may be formed so that a portion of the insulation layer 570 is exposed.

Referring to FIGS. 5 and 6, the plurality of layers 510 to 580 included in the printed circuit board 500 may be classified into two or more substrate layers. For example, the layer 510 as the base substrate, which is a type of insulation layer, and the first metal layer 520 may be classified as a first substrate layer, the first insulation layers 530 and the second metal layer 540 may be classified as a second substrate layer, the second insulation layers 550 and the third metal layer 560 may be classified as a third substrate layer, and the third insulation layers 570 and the fourth metal layer 580 may be classified as a fourth substrate layer. Such substrate layer classification is merely an example, but, without limitations thereto, may be classified in various ways. For example, one substrate layer may include two or more metal layers.

A signal line 430 may be formed based on at least one of the plurality of metal layers 520, 540, 560, and 580. For example, referring to FIGS. 4 and 5, the signal line 430 may be formed of the fourth metal layer 580 among the plurality of metal layers 520, 540, 560, and 580 and may be disposed on the third insulation layer 570.

For example, the fourth metal layer 580 may be formed in a line shape and may be disposed as the signal line 430 illustrated in FIG. 4 on the third insulation layer 570. The first slit 590 formed by etching at least a portion of the third insulation layer 570 may be positioned below at least a portion of the fourth metal layer 580. Accordingly, the signal line 430 having the fourth metal layer 580 formed in a line shape may be disposed to pass over the first slit 590. For example, the signal line 430 may pass over the first slit 590 in a direction perpendicular to the longitudinal direction of the first slit 590. Alternatively, the signal line 430 may be wired in a direction forming a predetermined angle with the longitudinal direction of the first slit 590 on a plane, and a portion of the signal line 430 may be wired to overlap the first slit 590 on a vertical line of the slit.

As shown in FIG. 6, the second slit 592 may be formed so that the metal layer 560 and at least a portion of the insulation layer 570 are etched into a shape necessary for each circuit to expose the insulation layer 560. The second slit 592 may be formed by etching the metal layer 560 and the insulation layer 570 when separation is required for insulation between various signals or power sources.

As in the case of FIG. 5, the fourth metal layer 580 may be formed in a line shape and may be disposed as the signal line 430 illustrated in FIG. 4 on the third insulation layer 570.

The second slit 592 formed by etching at least a portion of the third insulation layer 570 and the third metal layer 560 may be positioned below at least a portion of the fourth metal layer 580. Accordingly, the signal line 430 formed in a line shape of the fourth metal layer 580 may be disposed to pass over the area in which the second slit 592 is formed. For example, the signal line 430 may pass over the second slit 590 in a direction perpendicular to the longitudinal direction of the second slit 592.

In FIGS. 5 and 6, the insulation layers 530, 550, and 570 may include a support member and an elastic member. The support member may maintain the shape of the printed circuit board and support a plurality of elastic members and metal layers.

Referring to FIG. 4, in general, the impedance of a signal line may be maintained when the metal layers serving as a signal reference are uniformly disposed on the layers under where the signal line is disposed in a state in which the signal line is wired on the printed circuit board 400. In other words, when there is no discontinuous section of the reference plane for the signal line, distortion of the signal through the signal line may be prevented.

Further, if among the layers under the layer where the signal line is disposed, a metal layer is, even partially, etched, or a slit is formed in at least a portion of the insulation layer disposed over or under the metal layer, a discontinuous section is generated in the reference plane, and the arrangement in the vertical line is not uniform, causing a significant impedance peak in the signal line.

According, as shown in FIGS. 4 and 5, the impedance of the signal line 430 is varied due to the etched portions of the metal layer or the portion where the slit 440, 590, or 592 is formed, causing signal distortion and deteriorating communication quality.

An embodiment of the disclosure adopts an impedance matching element adjacent to the signal line to mitigate a drastic change in signal impedance due to a discontinuous section in the reference plane of the signal line or non-uniform arrangement.

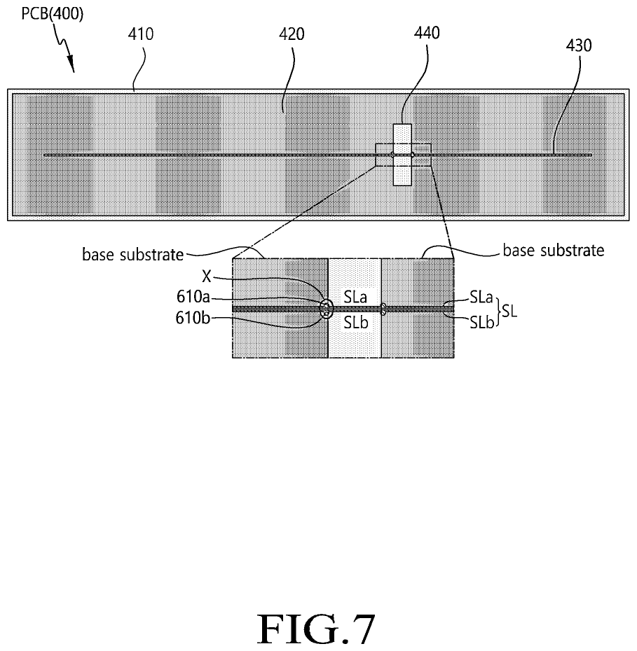

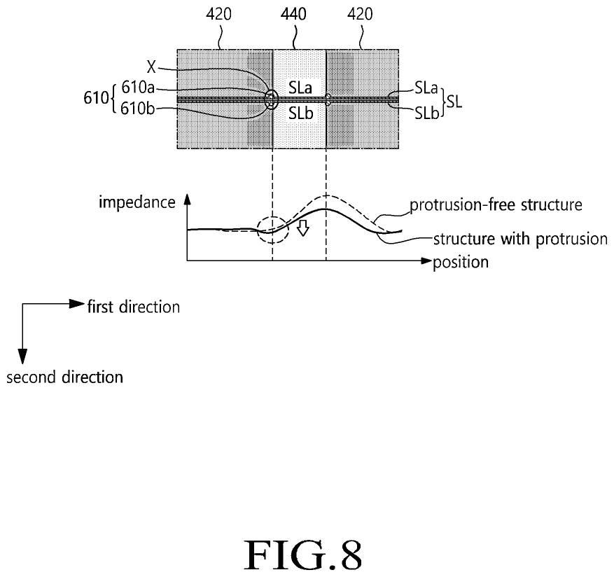

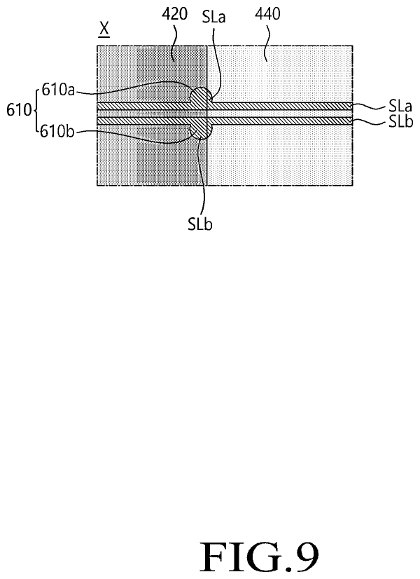

FIG. 7 is a cross-sectional view illustrating a printed circuit board having an impedance matching element according to an embodiment of the disclosure. FIG. 8 is a graph illustrating changes in impedance of a signal line when an impedance matching element is connected to a signal line and when an impedance matching element is not connected to a signal line according to an embodiment of the disclosure. FIG. 9 is an enlarged plan view illustrating a portion of an impedance matching element according to an embodiment of the disclosure.

Referring to FIG. 7, a printed circuit board (PCB) 400 includes a first substrate layer 410 and a second substrate layer 420. For convenience of description, only the first substrate layer 410 and the second substrate layer 420 of the multilayer structure of the printed circuit board are illustrated and represented, but the substrate layers constituting the multilayer structure of the printed circuit board 400 are not limited thereto.

The second substrate layer 420 may be disposed on the first substrate layer 410.

The second substrate layer 420 may be stacked on at least a portion of the first substrate layer 410, and may include a slit 440, signal lines SL (SLa and SLb), and impedance matching elements 610a and 610b connected to the signal lines SL. Here, the signal line SL may correspond to the signal line 430 of FIG. 4.

As an embodiment, referring to FIGS. 8 and 9, the signal lines SL may include a first signal line SLa and a second signal line SLb for transferring a differential signal.

The impedance matching element 610 (610a and 610b) may be integrally formed with the signal line SL.

Specifically, the impedance matching elements 610 may include a first impedance matching element 610a connected to the first signal line SLa and a second impedance matching element 610b connected to the second signal line SLb.

The first signal line SLa and the first impedance matching element 610a may be electrically connected to each other through physical contact. The second signal line SLb and the second impedance matching element 610b may be electrically connected to each other through physical contact.

The impedance matching element 610 may be formed in a protrusion shape protruding outward from the signal line SL. In other words, the impedance matching element 610 may be formed to protrude in a direction forming a vertical distance to the closest edge portion of the printed circuit board 400 from the center of the signal line SL.

The impedance matching element 610 may be formed in an area facing the slit 440 on the same layer of the printed circuit board 400 on which the signal line SL is disposed.

Referring to FIG. 8, it may be identified that, as compared with a protrusion-free structure, a structure with a protrusion mitigates the impedance peak of the signal line by temporarily decreasing an abrupt impedance change occurring in the boundary portion between the slit 440 and the signal line SL through the structure in which the impedance matching element 610 is connected to the signal line SL.

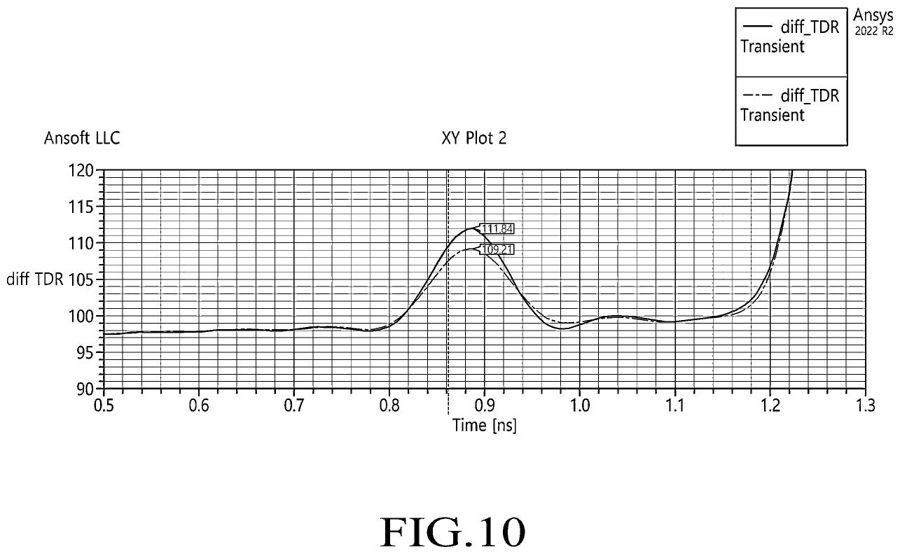

According to embodiments of the disclosure, it is possible to prevent or at least reduce distortion of a signal form to maintain communication quality by mitigating an abrupt impedance change through a structure in which an impedance matching element 610 is connected to at least a portion of a signal line SL adjacent to a boundary portion to a slit. FIG. 10 is a graph illustrating an impedance peak mitigating effect by an impedance matching element according to an embodiment of the disclosure.

Referring to FIGS. 7 and 10, e.g., when the impedance matching elements 610a and 610b are connected to the signal lines SLa and SLb in a structure in which a signal line having a radius of 100 μm line width is disposed around the slit 440, it may be identified that the impedance peak is mitigated by about 22% as compared to when the impedance matching elements 610a and 610b are not connected to the signal lines SLa and SLb.

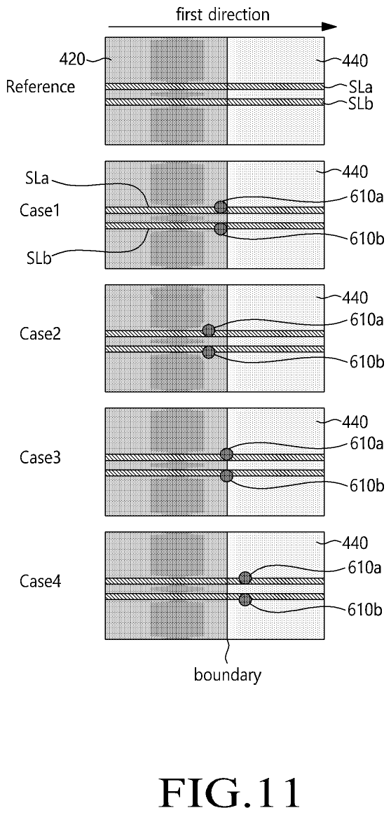

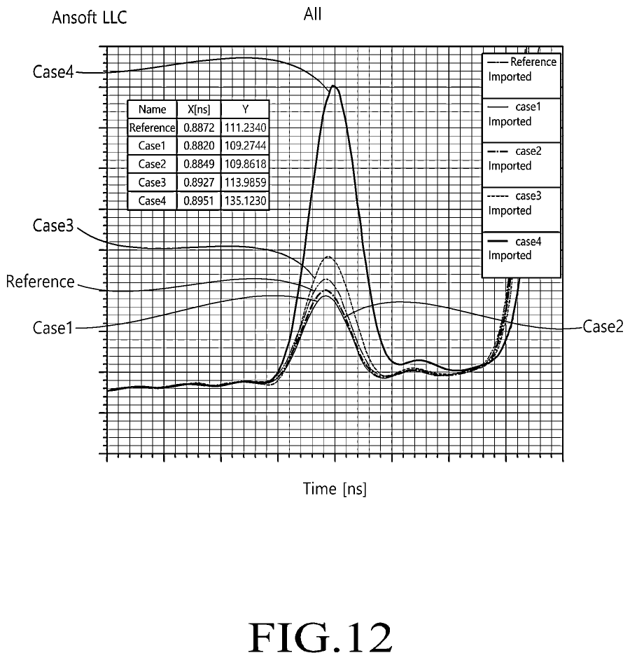

FIG. 11 illustrates an example of a placement position of an impedance matching element according to an embodiment of the disclosure. FIG. 12 is a graph illustrating a difference in impedance of a signal line according to a placement position of an impedance matching element according to an embodiment of the disclosure.

Referring to FIG. 11, the following four cases may be considered as the placement position of an impedance matching element according to an embodiment of the disclosure.

Referring to FIGS. 7 and 11, in the first case (case 1), the impedance matching elements 610a and 610b may be positioned on the second substrate layer 420 while contacting the boundary (i.e., side wall) of the slit 440. In other words, the impedance matching elements 610a and 610b may be formed on the second substrate layer 420 in contact with the boundary between the slit 440 and the printed circuit board 400, and may be formed to be connected to the signal lines SLa and SLb. For example, the impedance matching elements 610a and 610b may be positioned on the second substrate layer 420 while contacting a side wall of the slit 440.

Referring to FIGS. 7 and 11, in the second case (case 2), the impedance matching elements 610a and 610b may be spaced apart from the boundary of the slit 440 by a predetermined distance and may be positioned on the second substrate layer 420. In other words, the impedance matching elements 610a and 610b may be formed on the second substrate layer 420 spaced a predetermined distance apart from the boundary between the slit 440 and the printed circuit board 400, and may be formed to be connected to the signal lines SLa and SLb. For example, the impedance matching elements 610a and 610b may be positioned on the second substrate layer 420 while being spaced apart from a side wall of the slit 440.

Referring to FIGS. 7 and 11, in the third case (case 3), the impedance matching elements 610a and 610b may be positioned over the boundary of the slit 440. In other words, the impedance matching elements 610a and 610b may be formed on a boundary line corresponding to the boundary between the slit 440 and the printed circuit board 400. Accordingly, a portion of the impedance matching elements 610a and 610b may be formed on the second substrate layer 420, and the remaining other portion may be floating in a space corresponding to a vertical line of the slit 440, and the portion and the other portion of the impedance matching elements 610a and 610b may be formed to be connected to the signal lines SLa and SLb. For example, the impedance matching elements 610a and 610b may span a side wall of the slit 440.

Referring to FIGS. 7 and 11, the fourth case (case 4) may be a structure in which the impedance matching elements 610a and 610b are connected to the signal lines SLa and SLb to be positioned in a space corresponding to a vertical line of the slit 440 while being spaced apart from the boundary of the slit 440. In other words, in the fourth case, the impedance matching elements 610a and 610b may not be formed on the second substrate layer 420, but may be formed to be connected only to the signal lines SLa and SLb. For example, the impedance matching elements 610a and 610b may be spaced apart from a side wall of the slit 440 and float in a space corresponding to a vertical line of the slit 440.

Referring to FIG. 12, such a tendency may be identified that as the position of the impedance matching element 610a and 610b is closer to the boundary between the slit 440 and the printed circuit board 400, the impedance decreases and, as being farther away from the boundary between the slit 440 and the printed circuit board 400, the impedance increases.

Accordingly, it may be identified that an impedance mitigating effect may be obtained by disposing the impedance matching element 610a and 610b as close as possible to the start position of the slit 440, i.e., the boundary between the slit 440 and the printed circuit board 400.

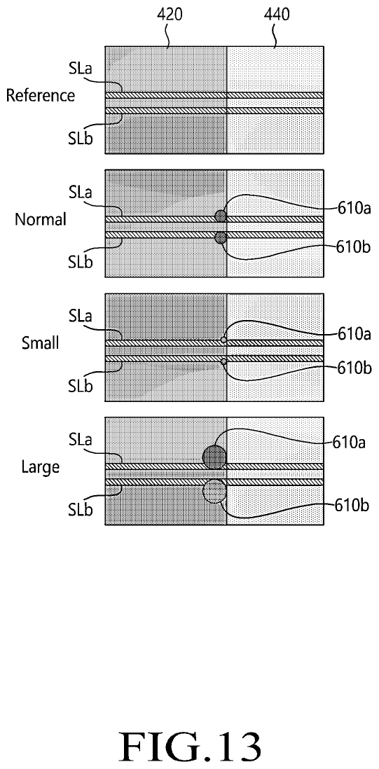

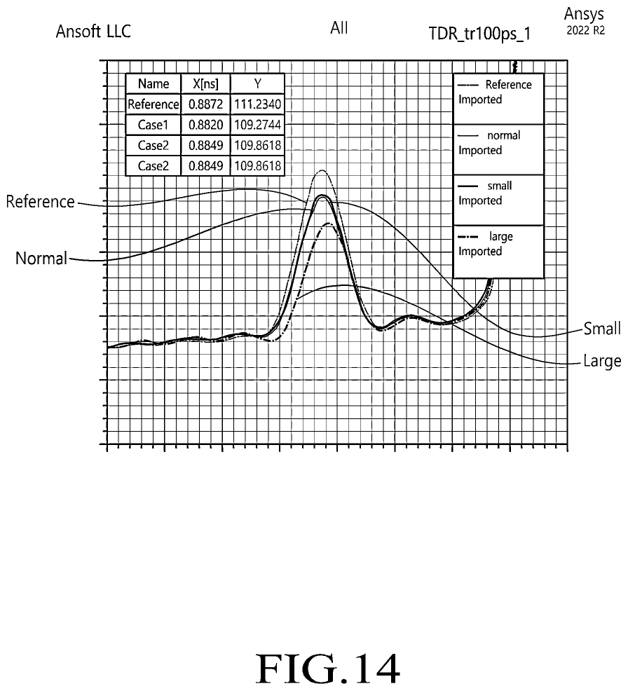

FIG. 13 is an example view illustrating various sizes of an impedance matching element according to an embodiment of the disclosure. FIG. 14 is a graph illustrating a difference in impedance of a signal line according to various sizes of an impedance matching element according to an embodiment of the disclosure.

Referring to FIG. 13, the sizes of the impedance matching elements 610a and 610b, i.e., the respective widths of the impedance matching elements 610a and 610b may be identical in radius to the respective widths of the signal lines SLa and SLb (Normal of FIG. 13). Alternatively, the respective widths of the impedance matching elements 610a and 610b may be smaller than or equal in radius to the respective widths of the signal lines SLa and SLb (Small in FIG. 13). For example, when the impedance matching elements 610a and 610b are circular, the radii may be ½ of the widths of the signal lines SLa and SLb, respectively.

Alternatively, the respective widths of the impedance matching elements 610a and 610b may be larger than or equal to the respective widths of the signal lines SLa and SLb (Large in FIG. 13). For example, when the impedance matching elements 610a and 610b are circular, the radii may be twice the widths of the signal lines SLa and SLb, respectively.

Referring to the graph of FIG. 14, it may be identified that as the size of each of the impedance matching elements 610a and 610b increases, the effect of decreasing the impedance peak increases. However, the effect of decreasing the impedance peak is not linear to the size of the impedance matching elements 610a and 610b.

The impedance matching element 610a and 610b has an effect of decreasing the impedance peak when connected to the signal line SL as compared with when not connected to the signal line, regardless of its size, and such a tendency is shown that as the size of the impedance matching element increases, the effect of decreasing the impedance peak increases within a predetermined range.

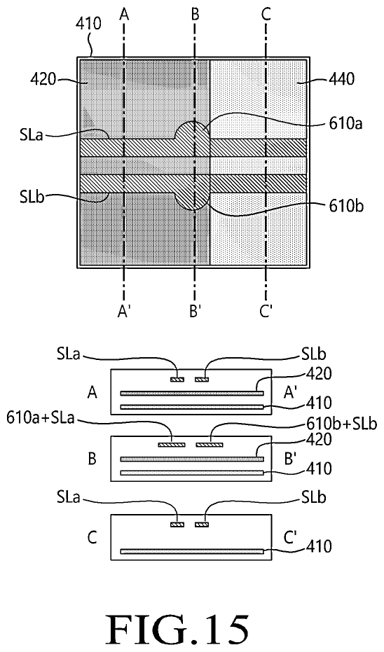

FIG. 15 is a plan view and cross-sectional view illustrating a printed circuit board having a platooning management entity according to an embodiment of the disclosure.

Referring to FIG. 15, a printed circuit board may be a multilayer substrate including at least two layers.

The cross section taken along the A-A′ portion may include a cross section of a lower insulation layer 410, an upper substrate layer 420, and a general signal line. The cross section of the signal line in the A-A′ portion is a cross section of only the signal line to which the impedance matching element is not connected. Specifically, the left side illustrates a cross section of the first signal line SLa and the right side illustrates a cross section of the second signal line SLb.

The cross section taken along the B-B′ portion may include a cross section of a lower insulation layer 410, an upper substrate layer 420, a signal line, and a portion of an impedance matching element. Specifically, the left side illustrates a cross section of a structure in which the first signal line SLa and the first impedance matching element 610a are connected, and the right side illustrates a cross section of a structure in which the second signal line SLb and the second impedance matching element 610b are connected.

Since the signal line and the impedance matching element are connected in each of the left and right cross sections of the B-B′ portion, the length of the width appearing in the cross section is longer than the cross section of only the signal line, which is the cross section taken along the A-A′ portion.

The cross section taken along the C-C′ portion may include a cross section of a lower insulation layer 410 and a signal line. The C-C′ portion is a portion in which a slit is formed, and is a portion in which the signal line passes, and thus, the cross section taken along the C-C′ portion may include a cross section of the lower insulation layer and a partial cross section of the signal line.

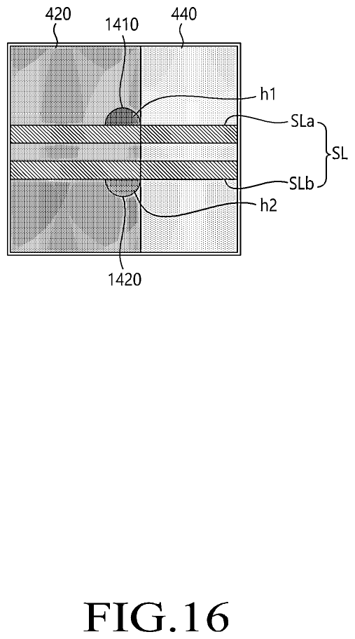

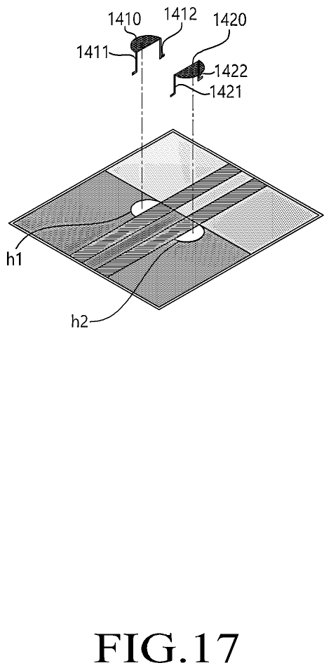

As illustrated in FIGS. 9 and 11, the impedance matching element may be integrated with the signal line, or as illustrated in FIGS. 16 and 17, structure in which the impedance matching element and the signal line are independently separated from each other may be connected to each other by fastening and may be detachable from each other.

The impedance matching element integrally formed with the signal line as illustrated in FIGS. 9 and 11 may be a welding pattern coupled to the signal line.

FIG. 16 is a plan view illustrating an example of an impedance matching element structure according to an embodiment of the disclosure. FIG. 17 is a perspective view illustrating a coupling structure between an impedance matching element and a printed circuit board according to an embodiment of the disclosure.

Referring to FIGS. 16 and 17, the impedance matching elements 1410 and 1420 may be coupled to the signal lines SL (SLa, and SLb) in a form detachable from the grooves h1 and h2 formed in the printed circuit board 400.

Specifically, as illustrated in FIG. 17, e.g., the impedance matching elements 1410 and 1420 formed of the same component as the signal lines SL and provided in a structure of being detachable from the grooves h1 and h2 formed in at least a portion of the printed circuit board 400 may be fitted into the grooves h1 and h2 formed in at least a portion of the second board layer 420.

In this case, the lower portion of the impedance matching elements 1410 and 1420 may further include fastening elements 1411, 1412, 1421, and 1422 that are detachable from the grooves h1 and h2. The fastening elements 1411, 1412, 1421, and 1422 may have the same material as the impedance matching elements 1410 and 1420. Alternatively, the fastening elements 1411, 1412, 1421, and 1422 may be insulating materials.

For example, the fastening elements 1411, 1412, 1421, and 1422 may be provided in the form of legs attached to the lower portions of the impedance matching elements 1410 and 1420, and the fastening elements 1411, 1412, 1421, and 1422 may be provided so that the ends of the fastening elements 1411, 1412, 1421, and 1422 partially protrude outward beyond the outer circumferences of the impedance matching elements 1410 and 1420 and are physically elastic, and may be fitted and fastened to the grooves h1 and h2.

The grooves h1 and h2 may be formed in a trench structure or a hole structure in at least a portion of the printed circuit board 400. The outer circumferences of the grooves h1 and h2 may have the same shape as the outer circumferences of the impedance matching elements 1410 and 1420. The sizes of the grooves h1 and h2 on a plane may be the same as or smaller than the sizes of the impedance matching elements 1410 and 1420 on a plane.

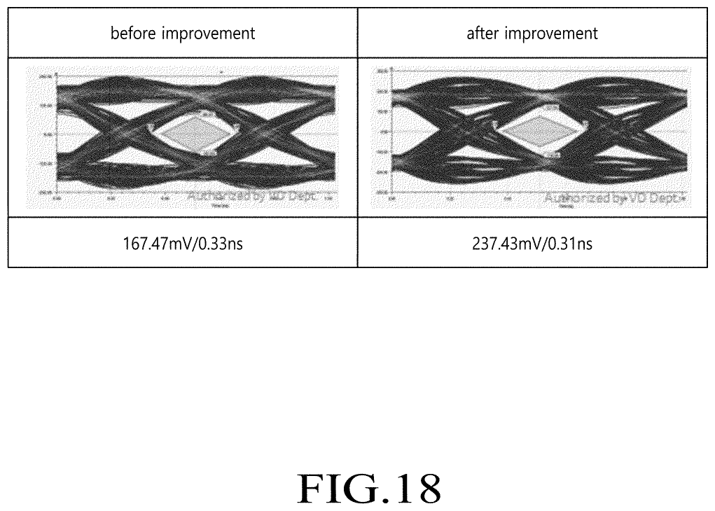

FIG. 18 is an eye diagram illustrating differential signal states before an impedance peak of a signal line is mitigated, which is generated by a slit formed in a printed circuit board, and after an impedance peak of a signal line is mitigated by an impedance matching element.

FIG. 18 illustrates differential signal waveforms before and after mitigating the impedance peak through an eye diagram showing an accumulated/superposed voltage waveform of an electrical signal on a time axis. In general, when the eye opening, which is the central portion of the eye diagram, is large, it means that digital signal quality is excellent, and when the eye opening is small or severely crushed, it means that digital signal quality is low.

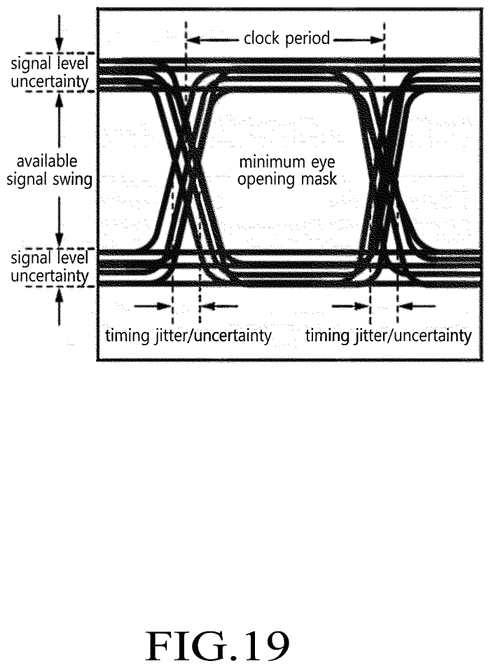

Since digital signals have high (1) and low (0) and represent binary numbers 1 and 0 in waveforms, the most ideal signal form should be square but, in reality, it is not so perfect. When the waveforms of these digital signals are superimposed on the time axis, the shape as shown in FIG. 19 is visible on the oscilloscope.

Referring to FIG. 18, when comparing the eye diagram (before mitigation) of the differential signal before the abrupt impedance change of the signal line passing through the slit is mitigated with the eye diagram (after mitigation) of the differential signal after the impedance matching element is connected to the signal line to mitigate the impedance peak, it may be identified that the eye opening is increased after the impedance peak is mitigated.

Embodiments of the disclosure described above are briefly described below.

A display device according to embodiments of the disclosure may comprise a display panel, and a printed circuit board directly or indirectly connected to the display panel and including a plurality of layers. The printed circuit board may include a first substrate layer, a second substrate layer disposed on the first substrate layer and having a slit formed in at least a portion thereof, a signal line disposed on the second substrate layer, wired in a direction forming a predetermined angle from a longitudinal direction of the slit, and passing over the slit such that a portion thereof overlaps the slit on a vertical line of the slit, and an impedance matching element connected to the signal line.

The impedance matching element may be configured integrally with the signal line.

The impedance matching element may be a welding pattern coupled to the signal line.

The impedance matching element may be detachably coupled to the signal line.

The display device may further comprise a dielectric layer disposed between the first substrate layer and the second substrate layer.

The impedance matching element may be formed in a protrusion shape protruding outward from the signal line.

The signal line may include a first signal line and a second signal line for transferring a differential signal. The impedance matching element may include a first impedance matching element connected to the first signal line and a second impedance matching element connected to the second signal line.

The impedance matching element may span a side wall of the slit.

The impedance matching element may be positioned on the second substrate layer while contacting a side wall of the slit.

The impedance matching element may be positioned on the second substrate layer while being spaced apart from a side wall of the slit by a predetermined distance.

The impedance matching element may be spaced apart from a boundary between the slit and the printed circuit board and floats in a space corresponding to a vertical line of the slit.

A width of the impedance matching element may be smaller than or equal to a width of the signal line.

A width of the impedance matching element may be larger than or equal to a width of the signal line.

A signal applied to the signal line may be a differential signal.

A printed circuit board according to another embodiment of the disclosure may comprise a first substrate layer, a second substrate layer disposed on the first substrate layer and including a slit, a signal line disposed on the second substrate layer, wired in a direction forming a predetermined angle from a longitudinal direction of the slit, and passing over the slit such that a portion thereof overlaps the slit on a vertical line of the slit, and an impedance matching element connected to the signal line.

A printed circuit board according to another embodiment of the disclosure may comprise a substrate layer including a slit, a signal line on the substrate layer, the signal line wired in a direction forming a predetermined angle from a longitudinal direction of the slit and passing over the slit such that a portion thereof may overlap the slit on a vertical line of the slit, and a first element and a second element for decreasing an abrupt change, caused by the slit, in impedance of the signal line. The first element may contact or be adjacent to a first side wall of the slit, and be connected to the signal line. The second element may contact or be adjacent to a second side wall of the slit opposite to the first side wall, and be connected to the signal line. Each of the first and second elements may be formed in a protrusion shape protruding outward from the signal line.

Embodiments of the disclosure may provide a printed circuit board and a display device including the same, which may prevent an abrupt change in impedance while having an effective multi-layer structure through a slit structure including a plurality of slits disposed to be spaced apart from each other for insulation between signal lines.

According to embodiments of the disclosure, it is possible to mitigate an impedance peak issue that occurs in a signal line caused by a slit.

According to embodiments of the disclosure, it is possible to mitigate an impedance peak by temporarily decreasing an abrupt change in impedance at a slit boundary by connecting an impedance matching element to a signal line.

According to embodiments of the disclosure, it is possible to maintain communication quality while preventing distortion of a signal shape by mitigating an abrupt change in impedance.

The above description has been presented to enable any person skilled in the art to make and use the technical idea of the disclosure, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the disclosure. The above description and the accompanying drawings provide an example of the technical idea of the disclosure for illustrative purposes only. That is, the disclosed embodiments are intended to illustrate the scope of the technical idea of the disclosure.

What is claimed:

1. A display device, comprising:
a display panel; and
a printed circuit board directly or indirectly connected to the display panel and including a plurality of layers, wherein the printed circuit board includes:
a first substrate layer;
a second substrate layer on the first substrate layer, the second substrate layer having a slit in at least a portion thereof;
a signal line on the second substrate layer, the signal line wired in a direction forming a predetermined angle from a longitudinal direction of the slit and passing over the slit such that a portion thereof overlaps the slit on a vertical line of the slit; and
an impedance matching element connected to the signal line.

2. The display device of claim 1, wherein the impedance matching element is integral with the signal line.

3. The display device of claim 1, wherein the impedance matching element is a welding pattern that is coupled to the signal line.

4. The display device of claim 1, wherein the impedance matching element is detachably coupled to the signal line.

5. The display device of claim 1, further comprising:
a dielectric layer between the first substrate layer and the second substrate layer.

6. The display device of claim 1, wherein the impedance matching element has a protrusion shape that protrudes outward from the signal line.

7. The display device of claim 1, wherein the signal line includes a first signal line and a second signal line that transfer a differential signal, and
wherein the impedance matching element includes a first impedance matching element connected to the first signal line and a second impedance matching element connected to the second signal line.

8. The display device of claim 1, wherein the impedance matching element spans a side wall of the slit.

9. The display device of claim 1, wherein the impedance matching element is on the second substrate layer while contacting a side wall of the slit.

10. The display device of claim 1, wherein the impedance matching element is on the second substrate layer while spaced apart from a side wall of the slit by a predetermined distance.

11. The display device of claim 1, wherein the impedance matching element is spaced apart from a side wall of the slit and the printed circuit board and floats in a space corresponding to the vertical line of the slit.

12. The display device of claim 1, wherein a width of the impedance matching element is smaller than or equal to a width of the signal line.

13. The display device of claim 1, wherein a width of the impedance matching element is larger than or equal to a width of the signal line.

14. A printed circuit board, comprising:
a first substrate layer;
a second substrate layer on the first substrate layer and including a slit;
a signal line on the second substrate layer, the signal line wired in a direction forming a predetermined angle from a longitudinal direction of the slit, and passing over the slit such that a portion thereof overlaps the slit on a vertical line; and
an impedance matching element connected to the signal line.

15. The printed circuit board of claim 14, wherein the impedance matching element is integral with the signal line.

16. The printed circuit board of claim 14, wherein the impedance matching element is a welding pattern coupled to the signal line.

17. The printed circuit board of claim 14, wherein the impedance matching element is detachably coupled to the signal line.

18. The printed circuit board of claim 14, wherein the impedance matching element has a protrusion shape that protrudes outward from the signal line.

19. The printed circuit board of claim 14, further comprising:
a plurality of elastic members on different layers and overlapping each other;
a plurality of supporting members each on a same layer as a respective one of the plurality of elastic members; and
at least one metal layer on a different layer from the plurality of elastic members and the plurality of supporting members.

20. A printed circuit board, comprising:
a substrate layer including a slit;
a signal line on the substrate layer, the signal line wired in a direction forming a predetermined angle from a longitudinal direction of the slit and passing over the slit such that a portion thereof overlaps the slit on a vertical line of the slit; and
a first element and a second element for decreasing an abrupt change, caused by the slit, in impedance of the signal line;
wherein the first element contacts or is adjacent to a first side wall of the slit, and is connected to the signal line;
the second element contacts or is adjacent to a second side wall of the slit opposite to the first side wall, and is connected to the signal line; and
each of the first and second elements is formed in a protrusion shape protruding outward from the signal line.
